(19) United States
(12) Patent Application Publication
(10) Pub. No.: US 2005/0167827 A1
(43) Pub. Date: Aug. 4, 2005

(54) Solder alloy and semiconductor device

(75) Inventor: Eiji Hayashi, Tokyo (JP)

Correspondence Address: MCDERMOTT WILL & EMERY LLP, 600 13TH STREET, N.W., WASHINGTON, DC, 20005-3096, US

(73) Assignee: RENESAS TECHNOLOGY CORP.

(21) Appl. No.: 11/029,368

(22) Filed: Jan. 6, 2005

(30) Foreign Application Priority Data
Jan. 30, 2004 (JP) JP2004-022598

(51) Int. Cl. H01L 23/495

(52) U.S. Cl. 257/734

(57) ABSTRACT

A lead-free solder alloy and a semiconductor device are provided, both of which achieve high interconnect reliability. Internal electrodes formed on the integrated circuit side of a semiconductor chip and bonding pads formed on the upper surface of a package substrate are connected through solder bumps, whereby the semiconductor chip is mounted on the package substrate. The solder bumps are made of a solder alloy containing 0 to 1.0 wt % Ag, 0.2 to 1.0 wt % Cu, and Sn as the remainder.

### BACKGROUND OF THE INVENTION

1. Field of the Invention

The present invention relates to lead-free solder and a semiconductor device including lead-free solder bumps.

2. Description of the Background Art

As one of semiconductor device assembly techniques, flip-chip bonding is known. This bonding technique is a method of bringing electrodes provided on the undersurface of a semiconductor element (semiconductor chip) and bonding pads provided on the upper surface of a circuit board (package substrate) into tight contact for bonding by heat and pressure. On the electrodes on the semiconductor chip and the bonding pads on the package substrate, solder bumps are previously provided.

Conventionally, tin-lead (Sn—Pb) eutectic solder is used for solder bumps. However in recent years, solder alloys containing no Pb, so-called lead-free solder, are widely used to minimize adverse effects on the environment during waste disposal of electronic components.

The conventional lead-free solder alloys used for solder bumps generally contain 3 to 4 weight percent (wt %) silver (Ag), 0.5 to 1 wt % copper (Cu), and tin (Sn) as the remainder. There have also been proposed (for example in Japanese Patent Application Laid-open No. 2002-239780) solder alloys for solder bumps which do not use expensive Ag as a raw material so much (2 wt % or less) and have excellent bonding reliability and excellent drop impact resistance.

With recent miniaturization and higher integration of semiconductor devices, the pitch of electrodes on a semiconductor chip is becoming finer. Along with this, the volume of solder bumps formed on those electrodes is rapidly decreasing. The lead-free solder has relatively poor ductility, and its influence is evident in small solder bumps. Thus, it is getting difficult to achieve sufficient interconnect reliability with conventionally appreciated compositions of solder alloys.

### SUMMARY OF THE INVENTION

An object of the present invention is to provide a lead-free solder alloy and a semiconductor device, both of which achieve high interconnect reliability.

According to a first aspect of the present invention, a solder alloy contains 1.0 or less wt % silver (Ag), 0.2 to 1.0 wt % copper (Cu), and tin (Sn) as the remainder.

According to a second aspect of the present invention, a solder alloy contains 0.2 to 1.0 wt % Cu, and Sn as the remainder.

According to a third aspect of the present invention, a semiconductor device includes a bump made of a solder alloy containing 1.0 or less wt % Ag, 0.2 to 1.0 wt % Cu, and Sn as the remainder.

According to a fourth aspect of the present invention, a semiconductor device includes a bump made of a solder alloy containing 0.2 to 1.0 wt % Cu, and tin Sn as the remainder.

The solder alloys according to the present invention have high interconnect reliability. Also, the operational reliability of the semiconductor device improves by including bumps made of those solder alloys.

These and other objects, features, aspects and advantages of the present invention will become more apparent from the following detailed description of the present invention when taken in conjunction with the accompanying drawings.

### BRIEF DESCRIPTION OF THE DRAWINGS

FIG. 1 shows a semiconductor device according to a preferred embodiment; and

FIGS. 2 through 5 show modifications to the preferred embodiment.

### DESCRIPTION OF THE PREFERRED EMBODIMENTS

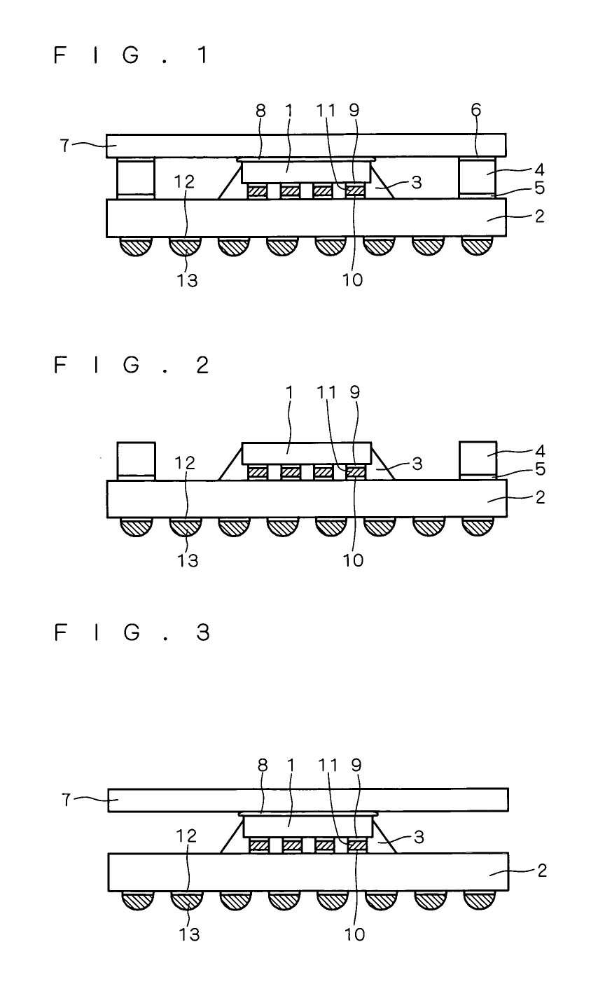

The inventor of the present invention conducted an experiment to find out the composition of solder alloys achieving high interconnect reliability. FIG. 1 shows a semiconductor device according to a preferred embodiment of the present invention. In the experiment, the semiconductor device with this configuration was put through an endurance test (temperature cycle test) against repetitive temperature changes. The following description is given of this experiment.

First, the configuration of the semiconductor device shown in FIG. 1 is described. The semiconductor device has a ball grid array structure and includes a semiconductor chip 1 and a board (package substrate) 2 for mounting the semiconductor chip 1. The semiconductor chip 1 is mounted facedown on the package substrate 2, with its integrated circuit side facing the package substrate 2. That is, internal electrodes 9 formed on the integrated circuit side of the semiconductor chip 1, and bonding pads 10 formed on the upper surface of the package substrate 2 are electrically and mechanically connected through solder bumps 11.

As previously described, the finer the pitch of the electrodes on the semiconductor chip 1, the more difficult it is to achieve sufficient interconnect reliability. Also, since usually a relatively large stress is applied between the semiconductor chip 1 and the package substrate 2 inside the semiconductor device, the solder bumps 11 between the semiconductor chip 1 and the package substrate 2 highly need to achieve especially high interconnect reliability.

The space between the semiconductor chip 1 and the package substrate 2 is filled with an underfill resin 3. The presence of the underfill resin 3 can relieve the stress applied from outside to soldered parts of the solder bumps 11 and thereby can improve the reliability of interconnection between the semiconductor chip 1 and the package substrate 2. On the upper surface of the package substrate 2, a stiffener 4 is provided with an adhesive tape 5. The stiffener 4 desirably has a coefficient of linear expansion close to that of the package substrate 2 in order to reduce the occurrence of stress, and is made for example of copper. The adhesive tape 5 is made, for example, of highly adhesive epoxy resin.

Further, for the purposes of improved heat dissipation of the semiconductor device and protection of the semiconductor chip 1, a heat spreader 7 is equipped on the semiconductor chip 1 with a radiation resin 8. The heat spreader 7 is also attached to the stiffener 4 with an adhesive tape 6. The adhesive tape 6 is made, for example, of highly adhesive epoxy resin. The radiation resin 8 is made, for example, of highly thermal conductive silver paste, so as to provide a thermal connection between the heat spreader 7 and the semiconductor chip 1.

On the undersurface of the package substrate 2, a plurality of external electrodes 12 are provided, on each of which a solder ball 13 is formed for mounting the semiconductor device on a motherboard or the like.

In the experiment, the temperature cycle test is performed on samples of the semiconductor device with the configuration of FIG. 1, by using different compositions of the solder bumps 11. The temperature cycle test includes a test of a single semiconductor device and a test of a semiconductor device mounted on a motherboard substrate. The solder bumps 11 used for the test are made of lead-free solder containing Ag, Cu, and Sn.

The result shows that the solder bumps 11 made of a solder alloy containing 0 to 1.0 wt % Ag, 0.2 to 1.0 wt % Cu, and Sn as the remainder achieve especially good results. More specifically, in the temperature cycle test of a single semiconductor device, all samples of the semiconductor device including the solder bumps 11 of the above composition had experienced no interconnect failures caused by the solder bumps 11 after 1,000 cycles of temperature changes between a low temperature of −55° C. and a high temperature of +125° C. Also, in the temperature cycle test of a single semiconductor device mounted on a motherboard substrate, all samples of the semiconductor device including the solder bumps 11 of the above composition had experienced no interconnect failures caused by the solder bumps 11 after 5,000 cycles of temperature changes between a low temperature of 0° C. and a high temperature of +100° C. Here, “0 wt % Ag” indicates that no Ag is contained (i.e., only Cu and Sn are contained).

Thus, the above experiment has shown that solder bumps made of a solder alloy containing 0 to 1.0 wt % Ag, 0.2 to 1.0 wt % Cu, and Sn as the remainder can achieve high interconnect reliability. That is, using lead-free solder of this composition as the solder bumps 11 in the semiconductor device shown in FIG. 1 improves the operational reliability of the semiconductor device.

As to the solder balls 13, since the pitch of the external electrodes 12 is generally greater than that of the solder bumps 11, it is possible to secure the volume of the solder balls 13. Also, since the stress applied to the solder balls 13 during semiconductor device mounting is relatively small, the use of conventional solder alloys (e.g., containing 3 to 4 wt % Ag, 0.5 to 1.0 wt % Cu, and Sn as the remainder) will achieve sufficient interconnect reliability. However of course like the solder bumps 11, a solder alloy containing 0 to 1.0 wt % Ag, 0.2 to 1.0 wt % Cu, and Sn as the remainder may be used for the purpose of further improving interconnect reliability.

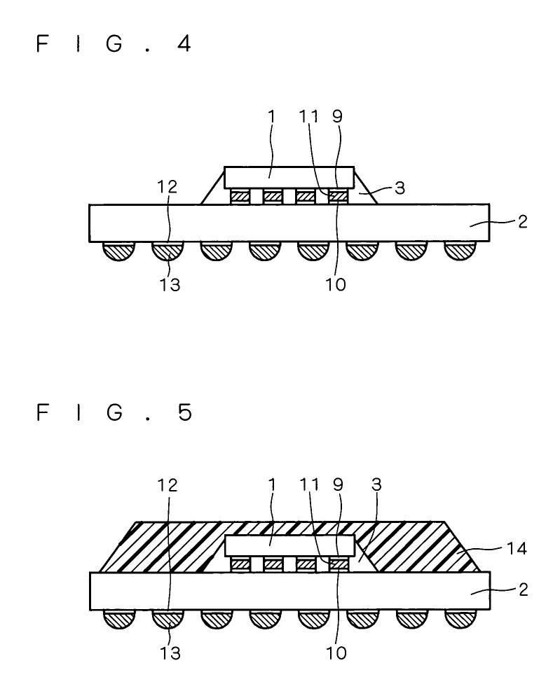

While the preferred embodiment of the present invention has described the semiconductor device including the stiffener 4 and the heat spreader 7 as shown in FIG. 1, the application of the present invention is not limited to this configuration. For example, the present invention is also applicable to various types of semiconductor devices such as the type not including the heat spreader 7 (FIG. 2), the type not including the stiffener 4 (FIG. 3), the type not including both the stiffener 4 and the heat spreader 7 (FIG. 4), and the type not including the stiffener 4 and the heat spreader 7 and instead covering the upper surfaces with a mold resin 14. In those cases also, high interconnect reliability can be achieved through the use of the solder bumps 11 and the solder balls 13 made of a solder alloy according to the present invention, which contains 0 to 1.0 wt % Ag, 0.2 to 1.0 wt % Cu, and Sn as the remainder.

While the invention has been shown and described in detail, the foregoing description is in all aspects illustrative and not restrictive. It is therefore understood that numerous modifications and variations can be devised without departing from the scope of the invention.

1. A solder alloy containing 1.0 or less weight percent (wt %) silver (Ag), 0.2 to 1.0 wt % copper (Cu), and tin (Sn) as the remainder.

2. A solder alloy containing 0.2 to 1.0 wt % Cu, and Sn as the remainder.

3. A semiconductor device comprising:
a bump made of a solder alloy containing 1.0 or less wt % Ag, 0.2 to 1.0 wt % Cu, and Sn as the remainder.

4. A semiconductor device comprising:
a bump made of a solder alloy containing 0.2 to 1.0 wt % Cu, and Sn as the remainder.
